(19) United States
(12) Patent Application Publication
(10) Pub. No.: US 2013/0045348 A1
(43) Pub. Date: Feb. 21, 2013

(54) HOUSING AND METHOD FOR MAKING THE SAME

(71) Applicants: CHWAN-HWA CHIANG, Shindian (TW); JIA-LIN CHEN, Shenzhen City (CN)

(72) Inventors: CHWAN-HWA CHIANG, Shindian (TW); JIA-LIN CHEN, Shenzhen City (CN)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/280,491

(22) Filed: Oct. 25, 2011

(30) Foreign Application Priority Data
Aug. 19, 2011 (CN) 201110239230.X

(51) Int. Cl. B32B 15/08; C23C 14/20; C23C 14/35; B32B 1/08

(52) U.S. Cl. 428/35.9; 204/192.14

(57) ABSTRACT

A housing includes a substrate, a base layer formed on the substrate, a metal layer formed on the base layer, and a topcoat layer formed on the metal layer. The metal layer is a silicon-aluminum alloy layer. A method for making the housing is also described.

### BACKGROUND

1. Technical Field

The present disclosure relates to housings and a method for making the housings.

2. Description of Related Art

Anodizing and paint spraying technologies are often used to give housings of electronic devices a more attractive appearance to consumers. However, the decorative coatings only have a single color and do not have metallic texture that is often desired.

Therefore, there is room for improvement within the art.

### BRIEF DESCRIPTION OF THE FIGURE

Many aspects of the housing and the method for making the housing can be better understood with reference to the following drawings. The components in the drawings are not necessarily drawn to scale, the emphasis instead being placed upon clearly illustrating the principles of the housing and the method. Moreover, in the drawings like reference numerals designate corresponding parts throughout the several views. Wherever possible, the same reference numbers are used throughout the drawings to refer to the same or like elements of an embodiment.

FIG. 1 is a cross-sectional view of an exemplary housing;

FIG. 2 is a schematic view of a vacuum sputtering device for fabricating the housing in FIG. 1.

### DETAILED DESCRIPTION

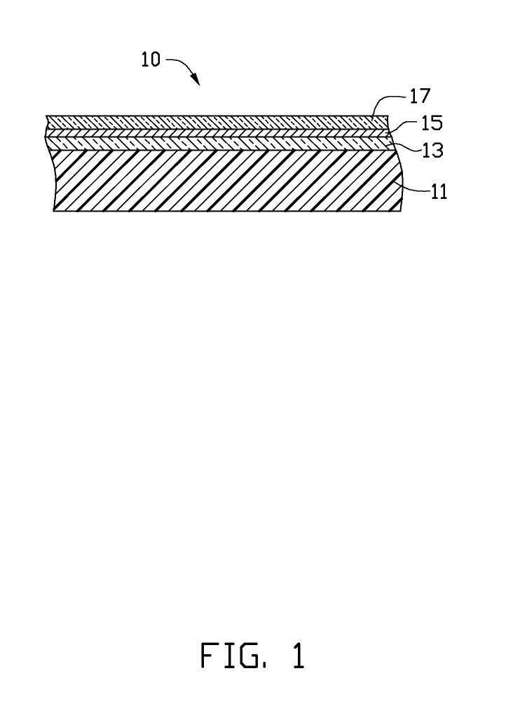

FIG. 1 shows a housing 10 according to an exemplary embodiment. The housing 10 includes a substrate 11, a base layer 13 formed on the substrate 11, a metal layer 15 formed on the base layer 13, and a topcoat layer 17 formed on the metal layer 15.

The substrate 11 is made of plastic.

The base layer 13 is an acrylic epoxy layer, and is a transparent ultraviolet curable resin layer. The degree of cure of the base layer 13 is about 50% to about 85%. The base layer 13 has a thickness of about 5 μm to about 30 μm.

The metal layer 15 is translucent silicon-aluminum alloy layer. The metal layer 15 has a thickness of about 10 nm to about 80 nm. The atomic percentage of silicon is about 10% to about 90% and the atomic percentage of aluminum is about 10% to about 90% in the metal layer 15.

The topcoat layer 17 is a transparent acrylic polyurethane layer. The degree of cure of the topcoat layer 17 is about 50% to about 85%. The topcoat layer 17 has a thickness of about 5 μm to about 20 μm. The topcoat layer 17 can protect the metal layer 15 from abrasion and scratch.

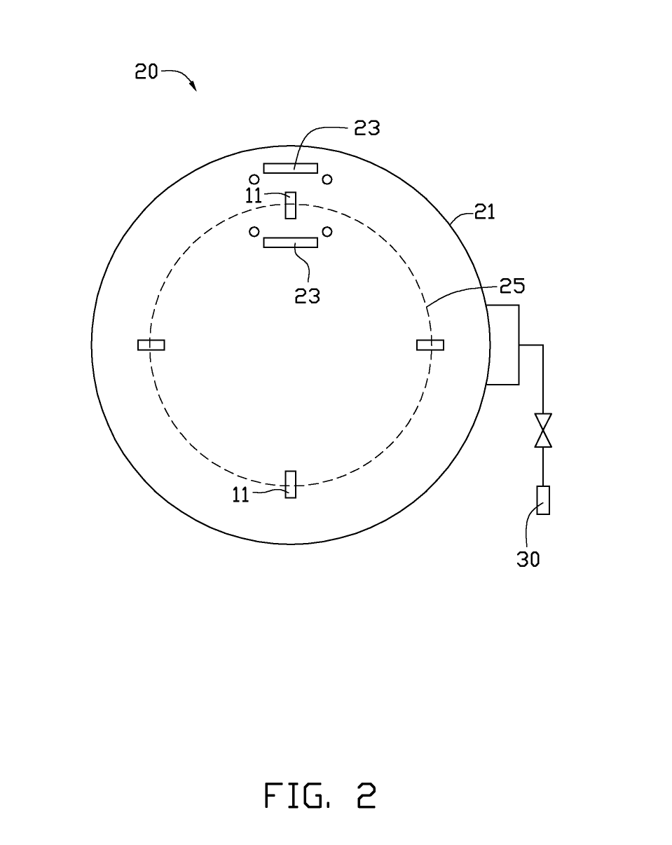

FIG. 2 shows a vacuum sputtering device 20, which includes a vacuum chamber 21 and a vacuum pump 30 connected to the vacuum chamber 21. The vacuum pump 30 is used for evacuating the vacuum chamber 21. The vacuum chamber 21 has silicon-aluminum alloy targets 23 and a rotary rack (not shown) positioned therein. The rotary rack holding the substrate 11 revolves along a circular path 25, and the substrate 11 is also rotated about its own axis while being carried by the rotary rack. The silicon-aluminum alloy targets 23 contain an atomic percentage of about 10%-90% of silicon and an atomic percentage of about 10%-90% of aluminum.

A method for making the housing 10 may include the following steps:

A substrate 11 made of plastic is provided.

A base layer 13 is formed on the substrate 11 by paint spraying or brushing. The base layer 13 is an acrylic epoxy layer, and has a thickness of about 5 μm to about 30 μm.

A metal layer 15 is magnetron sputtered on the base layer 13. Vacuum sputtering of the metal layer 15 is carried out in the vacuum chamber 21. The substrate 11 is positioned on the rotary rack. The vacuum chamber 21 is evacuated to about 8.0×10⁻³ Pa and the temperature of the vacuum chamber 21 is ambient temperature. Argon is used as the sputtering gas and is fed into the vacuum chamber 21 at a flow rate of about 80 sccm to about 120 sccm. The silicon-aluminum alloy targets 23 are supplied with electrical power of about 2.0 kw to about 3.5 kw. A negative bias voltage of about −0 V to about −100 V is applied to the substrate 11. Deposition of the metal layer 15 takes about 1 min to about 3 min The metal layer 15 is a silicon-aluminum alloy layer and has a thickness of about 10 nm to about 80 nm.

A topcoat layer 17 is formed on the metal layer 15 by paint spraying or brushing. The topcoat layer 17 is an acrylic polyurethane layer, and has a thickness of about 5 μm to about 20 μm.

It is understood that the housing 10 may also include a middle layer located between the metal layer 15 and the topcoat layer 17 to increase the bond between the metal layer 15 and the topcoat layer 17.

The base layer 13, metal layer 15 and topcoat layer 17 formed on the substrate 11 may have optical interference effect, which makes the housing 10 have a colorful rainbow appearance and good metallic texture. Thus, the appearance of the housing 10 is improved. Furthermore, the housing is insulative.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A housing, comprising:
a substrate;
a base layer formed on the substrate, the base layer being an acrylic epoxy layer;
a metal layer formed on the base layer, the metal layer being a silicon-aluminum alloy layer and containing about 10%-90% of silicon and 10%-90% of aluminum by atomic percentage; and
a topcoat layer formed on the metal layer, the topcoat layer being an acrylic polyurethane layer.

2. The housing as claimed in claim 1, wherein the substrate is made of plastic.

3. The housing as claimed in claim 1, wherein the base layer has a thickness of about 5 μm to about 30 μm.

4. The housing as claimed in claim 1, wherein the metal layer has a thickness of about 10 nm to about 80 nm.

5. The housing as claimed in claim 1, wherein the topcoat layer has a thickness of about 5 μm to about 20 μm.

6. The housing as claimed in claim 1, wherein the degree of cure of the base layer is about 50% to about 85%.

7. The housing as claimed in claim 1, wherein the degree of cure of the topcoat layer is about 50% to about 85%.

8. A method for making a housing, comprising:
providing a substrate;
forming a base layer on the substrate, the base layer being an acrylic epoxy layer;
forming a metal layer on the base layer, the metal layer being a silicon-aluminum alloy layer and containing about 10%-90% of silicon and 10%-90% of aluminum by atomic percentage; and
forming a topcoat layer formed on the metal layer, the topcoat layer being an acrylic polyurethane layer.

9. The method as claimed in claim 8, wherein magnetron sputtering the metal layer uses argon gas as the sputtering gas and the argon gas has a flow rate of about 80 sccm to about 120 sccm; uses silicon-aluminum alloy targets and the silicon-aluminum alloy targets are supplied with a power of about 2.0 kw to about 3.5 kw; a negative bias voltage of about −0 V to about −100 V is applied to the substrate.

10. The method as claimed in claim 9, wherein the silicon-aluminum alloy targets contains about 10%-90% of silicon and 10%-90% of aluminum by atomic percentage.

11. The method as claimed in claim 10, wherein vacuum sputtering the metal layer takes about 1 min to about 3 min.

12. The method as claimed in claim 8, wherein the substrate is made of plastic.

13. The method as claimed in claim 8, wherein the base layer has a thickness of about 5 μm to about 30 μm.

14. The method as claimed in claim 8, wherein the metal layer has a thickness of about 10 nm to about 80 nm.

15. The method as claimed in claim 8, wherein the topcoat layer has a thickness of about 5 μm to about 20 μm.
